(19) United States
(12) Patent Application Publication
(10) Pub. No.: US 2001/0041217 A1
(43) Pub. Date: Nov. 15, 2001

(54) DRY PROCESS FOR COATING TITANIA PARTICLES

(76) Inventors: ANGEL SANJURJO, SAN JOSE, CA (US); KAI HUNG LAU, CUPERTINO, CA (US)

Correspondence Address: BRET FIELD, BOZICEVIC FIELD & FRANCIS LLP, 200 Middlefield Road, SUITE 200, Menlo Park, CA, 94025, US

(21) Appl. No.: 09/410,335

(22) Filed: Oct. 1, 1999

Related U.S. Application Data
(60) Provisional application No. 60/102,830, filed on Oct. 2, 1998.

(51) Int. Cl. C23C 16/00

(52) U.S. Cl. 427/213; 427/255.393; 427/255.27

(57) ABSTRACT

Dry processes for coating titania particles, as well as the coated titania particles produced thereby, are provided. In the subject processes, a moving bed of titania particles is contacted with a gaseous first reactant under conditions sufficient for the first reactant to adsorb on the surface of the particles. Next, the particles having the first reactant adsorbed to their surface are contacted with a gaseous second reactant under conditions such that the second reactant reacts with the surface adsorbed first reactant to produce a product on the surface and in turn yield titania particles coated with a compact layer of the resultant product. The resultant coated titania particles find use in a variety of applications, including as pigments in paints and cosmetics.

### TECHNICAL FIELD

The present invention relates generally to inorganic particulate processing, particularly to methods of coating inorganic particulates, and more specifically to methods of coating titania particles.

### BACKGROUND

Fine particles are components in many different products and find use in many different applications, e.g. in paints, as pigments, as fillers, as carriers, as absorbers, as coatings, and the like. In many applications, the particle surface comes into contact with a carrier liquid, gas, or a solid. Therefore, the chemistry at the surface of the particle may have a significant impact on the particle properties, including its ability to disperse; its corrosion resistance; or its adherence; and the like.

Fine particles of titania (TiO₂) particles find use in many applications. TiO₂ particles can be produced by a variety of process including: (a) an acid digestion process in which a solution, such as TiO⁺²SO₄ is obtained, and from which TiO₂ is precipitated; and (b) gas phase processes where TiCl₄ is burned in an oxygen flame to yield TiO₂ fumes. See also U.S. Pat. No. 4,732,750, the disclosure of which is herein incorporated by reference.

In many applications, such as in paints, it is desirable to coat titania particles with a thin layer of a protective, dielectric, surface-wetable coating. In paints, for example, such coatings can improve the ability of the particles to disperse in the paint composition, as the dispersion of the titania particles in the paint depends primarily on the surface chemistry of the TiO₂ and its interaction with the liquid media of the paint. Furthermore, once a paint is applied, it is also known that further interaction between the TiO₂ pigment and the polymeric matrix of the paint may occur. For example, degradation of coatings known as “chalking” is due to the photo induced oxidation of the polymer by holes produced in TiO₂. When light of the appropriate wavelength arrives to the TiO₂ particles, it can promote an electron from the valence band to the conductor band, leaving a hole behind. The positive hole may in turn oxidize (burn) the polymer by robbing it of an electron that falls in the hole of the TiO₂ surface. The paint becomes yellowish-brown and the pigment can be rubbed off the paint. To prevent this degradation, pigment manufactures add chemistry to their TiO₂ suspensions or particles so that the surface of the pigment is coated with a layer of a dielectric, Silica (SiO₂) and Al₂O₃ (alumina) are commonly used for this purpose. Thus, coating processes for titania particles are industrially important.

Many wet coating techniques have been proposed and developed for coating titania particles. However, wet processes are not entirely satisfactory. A limitation of wet processes is that such processes require a control of the solution chemistry which then limits the flexibility of the approach, and it requires drying or calcination at the end of the coating which increases the cost.

As such, the development of a dry phase process that can coat in the gas phase such that the titania particles can be used directly from the reactor is of interest. Also of interest is the development of a process that increases the flexibility of the deposition process and is not constrained by the constrictions imposed by a liquid-solid interface.

### SUMMARY OF THE INVENTION

Dry processes for producing coated titania particles, as well as the particles produced thereby, are provided. In the subject processes, a moving bed, e.g. fluidized bed, of titania particles is contacted with a gaseous first reactant under conditions sufficient for the first reactant to adsorb to the surface of the titania particles. The resultant titania particles having the first reactant adsorbed to their surface are then contacted with a gaseous second reactant under conditions sufficient for the second reactant to react with the first reactant on the particle surface and produce a product. The process results in titania particles coated with a compact layer of the resultant product. The resultant product coated particles find use in a variety of applications, including as pigments in paints and cosmetics.

It is accordingly an object of the invention to address the above-mentioned need in the art by providing a dry process for producing coated titania particles.

It is another object of the invention to provide compact coated titania particles.

Additional objects, advantages and novel features of the invention will be set forth in part in the description which follows, and in part will become apparent to those skilled in the art upon examination of the following, or may be learned by practice of the invention.

### DEFINITIONS

As used herein all reference to the Periodic Table of the Elements and groups thereof is to the version of the table published by the Handbook of Chemistry and Physics, CRC Press, 1995, which uses the IUPAC system for naming groups.

### DETAILED DESCRIPTION OF THE INVENTION

Dry processes for preparing coated metal oxide particles, e.g. titania particles, as well as the resultant coated particles, are provided. In the subject processes, a moving bed of metal oxide, e.g. titania particles, is first contacted with a gaseous first reactant in a manner such that the gaseous first reactant adsorbs to the surface of the titania particles. Next, the resultant particles having the first reactant adsorbed to their surface are contacted with a gaseous second reactant under conditions sufficient for the gaseous second reactant to react with the adsorbed first reactant on the particle surface. The process results in a metal oxide particles coated with a compact layer of the product produced upon reaction of the first and second reactants. The resultant coated particles find use in a variety of different applications. For example, coated titania particles produced by the subject methods find use in applications such as pigments for use in paints, cosmetics and the like.

Before the present processes and products are disclosed and described, it is to be understood that this invention is not limited to specific processes, particles or the like, as such may vary. It is also to be understood that the terminology used herein is for the purpose of describing particular embodiments only and is not intended to be limiting.

It must be noted that as used in this specification and the appended claims, the singular forms “a,” “an,” and “the” include plural reference unless the context clearly dictates otherwise. Unless defined otherwise all technical and scientific terms used herein have the same meaning as commonly understood to one of ordinary skill in the art to which this invention belongs.

As summarized above, the subject invention is directed to a dry process of coating metal oxide, e.g. titania particles, with a compact outer layer, where in many embodiments the material of the outer layer is a dielectric material. As the subject process is a dry process, there is no step in the subject process that involves the contact of the metal oxide particles with a fluid medium, such as an aqueous or non-aqueous fluid medium. Instead, the reactants that produce the thin coating on the particle are in gaseous phase. As indicated above, the subject methods are directed, in the broadest sense, to methods of preparing coated metal oxide particles. However, for purposes of further illustration, the subject invention is now discussed further in terms of the preparation of coated titania particles.

The particles coated by the subject dry process are particles of titania, i.e. titanium dioxide, TiO₂, titanic anhydride, titanium oxide, titanium white. The preparation of titania particles is well known to those of skill in the art. See Faith, Keyes & Clark's Industrial Chemicals (F. A. Lowenheim, M. K. Moran eds)(Wiley-Interscience, New York, 4^{th} ed.) (1975) pp 814-821; U.S. Pat. No. 2,760,874; Czandema et al., J. Am. Chem. Soc. (1957) 79:5407; and Brittain et al., Analytical Profiles of Drug Substances and Excipients (H. G. Brittain ed.) (Academic Press, San Diego)(1992) pp 659-691. See also U.S. Pat. No. 4,732,750, the disclosure of which is herein incorporated by reference. The titania particles that are coatable by the subject processes have a diameter that generally ranges from the submicron level to greater than 100μ, usually from about 0.01 to 100μ, and more usually from about 0.10 to 100μ.

In the subject processes, the first step is to provide a moving bed of the titania particles. As such, the particles will be placed or introduced into a moving bed reactor, where by moving bed reactor is meant a reactor that is capable of continuously moving the particles relative to each other, e.g. through rotation, agitation, ultrasonic means, etc. Of particular interest is a fluidized bed reactor in which the titania particles (i.e. titania substrate) are present in a reactor on a fluidizing medium, as is known in the art. Suitable fluidized bed reactors include those described in U.S. Pat. Nos. 5,895,817; 5,879,638; 5,855,678; 5,836,257; 5,801,265; 5,779,989; 5,763,541; 5,707,591; 5,700,432; 5,700,431; 5,670,121; 5,656,243; 5,627,243; 5,573,689; 5,476,639, the disclosures of which are herein incorporated by reference. The reactor may be a continuous or batch-type apparatus. The fluidizing medium that is employed may be any gaseous medium that is inert with respect to the substrate particles, as well as the first and second reactants, described in greater detail below. Examples of gaseous fluidizing mediums include: air, Argon, Nitrogen, Helium, CO₂, steam, air. The particles may be introduced into the reactor using any convenient protocol, where the amount of particles introduced will necessarily depend on the nature of the reactor, including the physical parameters thereof.

Where the reactor is a fluidized bed reactor, the flow rate of the fluidizing medium or gas flowing through the bed may vary, depending upon the size and shape of the titania particles, as well as the temperature and pressure of the gas. Usually a linear flow rate of from about 1 to about 10, and in certain embodiments 5 to 10, centimeters/second will be employed. The height of the fluidized bed may vary considerably, but must be sufficiently high, with respect to the flow rate through the reactor, to permit the necessary minimum residence time for the reactants to produce the coating on the particle. The fluidized bed may be heated by any conventional means such as preheating the fluidizing gas before it enters the fluidized bed reactor or by internal heating coils within the reactor, external heating coils around the outside of the reactor walls, or by electromagnetic means, such as rf, microwave, arc, etc. The pressure within the fluidized bed reactor will generally be only slightly above ambient to permit sufficient fluidization of the bed by the incoming gas pressure. However, pressures ranging from as little as 1 Torr to as much as 1500 Torr or higher (e.g. 15000 Torr), preferably from about 100 Torr to about 1100 Torr, and most preferably from about 700 Torr to about 800 Torr, may be utilized in the reactor.

Following fluidization of the titania particles in the reactor, the gaseous first reactant is introduced into the reactor in a manner sufficient such the gaseous first reactant molecules adsorb to the surface of the particles. In certain embodiments of the invention, the amount of gaseous first reactant that is introduced will be such that at least a significant fraction of, if not substantially all of, the first reactant gaseous molecules are adsorbed to the particle surfaces, where by significant fraction is meant at least about 10 volume %, usually at least 50 volume %, and by substantially all is meant at least about 80 volume %, usually at least about 85 volume % and more usually at least 90 volume %.

The gaseous first reactant will be a reactant that is capable of adsorbing to the surface of the titania particles and that reacts with the second reactant to produce the desired coating material or product. Generally, the first reactant will be a reactant with a dipole moment of greater than 1 debye. As such, suitable reactants include: H₂O, NH₃, H₂O₂, ROH (wherein R is an organic radical) that may be mixed with O₂, O₃, N₂O and the like. In many embodiments, e.g. where one desires to produce a silica coating on the surface of the titania particles, H₂O is the preferred first reactant. The gaseous H₂O is introduced into the fluidized bed reactor using any convenient protocol, generally through a feed through line into the reactor.

The contents of the reactor are maintained at temperature sufficient for the first reactant molecules to adsorb to the particle surfaces. The temperature will necessarily vary depending on the nature of the first reactant, but generally the temperature will be at or slightly below the desorption point of the first reactant, such that less than 0.01 of a monolayer is adsorbed. As such, where water vapor is the first reactant, the average temperature of the contents of the fluidized bed, at least in the zone of the fluidized bed in which the adsorption takes place, will be maintained at a value of less than about 400° C., usually less than about 200° C. and more usually less than about 100° C.

In order to enhance the adsorption of the first reactant to the particle surface, the particles may be pre-treated in a number of different ways. By “enhance the adsorption” is meant the surface of the particles is treated in a manner such the temperature at which first reactant desorption from the particle surface occurs is raised as compared to the untreated particle, i.e. a control. As such, in particles that are treated to enhance the adsorption of the first reactant, the kT will be increased as compared to the non-treated particles, where the amount of increase will generally be at least 10%, usually at least about 15% and more usually at least about 20%, where the amount of increase in value may be as high as 50% or higher. Pretreating the particles to increase the kT (i.e. temperature at which the first reactant desorbs from the particles) results in the ability to contact the first reactant with the second reactant, described infra, at higher temperatures as compared to the non-treated particles.

The particles may be pretreated in various ways. In some embodiments, the particles may be pretreated with an agent that has a high affinity for the first reactant. For example, in situations where water vapor is the first reactant, treatment with ions having high heats of hydration finds use, where ions having high heats of hydration include Li⁺, Ce^{30 3}, Ce⁺⁴ and the like. Also of interest is pretreatment of the particles with acidic compounds that adsorb the first reactant. For example, where the first reactant is water, pretreatment with acidic compounds such as boric oxide, phosphate containing compounds, and the like, find use. Other methods of interest include those in which the particle surface is pretreated with a compound which, in turn, interacts with the first reactant in a manner that results in dπ-pπ bonding. Any convenient means of enhancing the adsorption of the first reactant to the particle surface may be employed. In the subject methods, the agent with which the particles are pretreated may be contacted with the particles prior to contact with the first reactant or continuously during the coating process, depending on the particular nature of the reactants being employed.

Adsorption of the first reactant molecules, e.g. water molecules, to the titania particle surface results in the production of first reactant adsorbed titania particles. Thus, in those embodiments in which the first reactant is water, the adsorption step of the subject process results in the production of H₂O adsorbed titania particles. As demonstrated above, the first reactant may be physiadsorbed or chemiadsorbed to the particle surface, with the only limitation being that the adsorbed reactant must be capable of heterogeneously reacting with the second reactant.

The next step in the subject process is to introduce a gaseous second reactant into the fluidized bed reactor under conditions sufficient for the second reactant to react with the adsorbed first reactant at the particle surface to produce at least a monolayer, and preferably a compact layer, of the product produced by the reaction of the first and second reactants. In the broadest sense, the second reactant will be a reactant that is capable of reacting with the first reactant in order to produce a product that makes up the desired coating of the titania particle. For example, where one is practicing the invention in order to produce a dielectric coating on the titania particles, the second reactant will be a reactant that reacts with the first reactant to produce the dielectric material of the desired coating.

The particular second reactant that is chosen will necessarily depend on the nature of the of the desired coating. Generally, the second reactant may be a compound that comprises one of the following elements: Al, B, Ge, Ga, Mg, Ca, Ba, Zr, Ti, V, Ta, P and Si, such as AlCl₃, TIBA, TiCl₄, Ti subhalides, ZrOCl₂, etc. In many embodiments, the desired coating is silica. In such embodiments, the second reactant will be a Si containing reactant, particularly a silicon halide, such as SiCl₄, or an organosilicon, e.g. TEOS.

The amount of the second reactant gas will generally be at least a slight stoichiometric excess over what is required to theoretically react with all of the adsorbed first reactant molecules, such that substantially all of the adsorbed first reactant molecules are consumed in the reaction to produce product. As such, the amount of excess will generally be at least about 1 mole %, usually at least about 2 mole % and in certain embodiments at least about 5 mole %.

The temperature at which the second reactant is contacted with the first reactant adsorbed particles, at least the temperature in the zone of the fluidized bed reactor in which second reactant contact occurs, may be the same as or different from the temperature at which the first reactant is contacted with the titania particles. Where the temperature is different, the amount of difference may be small, being between about 1 and 10 %, usually between about 5 and 10%, or may be large, being greater than about 50% or 75% or higher (e.g. 200%), as well as somewhere in between.

Upon contact of the first reactant adsorbed particles with the second reactant, the first and second reactant react at the surface of the particle to result in a heterogenous (i.e. on the surface) deposition of the product of the first and second reactants. The deposited product may be a monolayer thick or much thicker, where the thickness of the deposited layer will generally range from a monolayer to about 100μ or greater. Where the deposited layer is more than just a monolayer in thickness, the resultant deposited monolayer will form a compact coating surrounding the titania particle, where the compact coating will be substantially pinhole free.

The resultant titania particles are coated with a compact layer of a material that is the reaction product of the first and second reactants. By selecting the appropriate first and second reactants, the process can be used to coat the particles with a variety of different materials. Materials that may be coated on the particles using the subject processes include: alumina, zirconia, silica and the like, where the use of the process to coat titania particles with silica is particularly preferred in many embodiments of the invention. In certain embodiments, the process may be used to introduce one or more concentric coating layers onto the surface of the base particle. For example, a first layer may be introduced that smooths the base particle surface. Overlaying this first layer may be a second layer that modulates the optical or electrical properties of the particle. A final outer layer may encompass these two prior layers, where the final outer layer modulates the dispersion or rheology properties of the particle in a given medium.

The resultant coated titania particles find use in a variety of different applications. For example, silica coated titania particles produced according to the subject invention find use as pigments in paints, cosmetics and similar products, where such uses are known to those of skill in the art. Other applications in which the subject coated titania particles find use include as fillers, carriers, absorbers, coatings, and the like.

The following examples are offered by way of illustration and not by way of limitation.

### EXPERIMENTAL

### EXAMPLE 1

A volume of titania particles is introduced into a standard fluidized bed reactor where the fluidizing medium is argon. The temperature inside the reactor is maintained at 99° C. The settings on the reactor are chosen to produce a fluidized bed of the titania particles in the reactor. Next, water vapor is introduced into the reactor through a gaseous feed line and a sufficient period of time is allowed to pass for the water molecules to adsorb to the surface of the titania particles. Adsorption of the water molecules onto the surface of the fluidized titania particles results in the production of water adsorbed titania particles. Next, a slight excess of gaseous SiCl₄ is introduced into the reactor through a gaseous feed line. Contact of the gaseous SiCl₄ molecules with the adsorbed water molecules results in a heterogenous reaction on the surface of the titania particles to produce silica. The reactor contains at least a zone where the temperature can be 900° C. and the coating is dried and sintered. As a result, titania particles coated with a compact layer of silica are produced.

It is evident from the above results and discussion that an improved process for coating titania particles is provided. As the subject process is a dry process, it provides for distinct advantages over corresponding wet processes that have been previously employed. Such advantages include the ability to use the coated particles immediately from the reactor and freedom from the constraints imposed by solid liquid interface chemistry. As such, the subject invention provides for a significant contribution to the art.

All publications and patent applications cited in this specification are herein incorporated by reference as if each individual publication or patent application were specifically and individually indicated to be incorporated by reference. The citation of any publication is for its disclosure prior to the filing date and should not be construed as an admission that the present invention is not entitled to antedate such publication by virtue of prior invention.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

1. A dry process for coating a metal oxide particle, said process comprising:
contacting a moving bed of metal oxide particles in a moving bed reactor with a first reactant in a manner sufficient for said first reactant to adsorb to the surface of said metal oxide particles to produce first reactant adsorbed titania particles; and
contacting said first reactant adsorbed metal oxide particles with a second reactant under conditions sufficient for said second reactant to react with substantially all of said adsorbed first reactant to produce a coating of a product on the surface of said metal oxide particles.

2. The process according to claim 1, wherein said first reactant has a dipole moment of greater than 1 debye.

3. The process according to claim 2, wherein said first reactant is selected from the group consisting of: H₂O, NH₃, ROH, H₂O₂, O₂, O₃ and N₂O.

4. The process according to claim 1, wherein said second reactant comprises an element selected from the group consisting of: Al, B, Ge, Ga, Mg, Ca, Ba, Zr, Ti, V, Ta and P.

5. The process according to claim 1, wherein said second reactant comprises Si.

6. The process according to claim 5, wherein said second reactant is selected from the group consisting of silicon halides and organosilicons.

7. The process according to claim 1, wherein said product is a dielectric.

8. The process according to claim 7, wherein said dielectric is selected from the group consisting of silica and alumina.

9. The process according to claim 1, wherein said metal oxide particle is a titania particle.

10. A dry process for coating a titania particle with a compact silica layer, said process contacting a fluidized bed of titania particles in a fluidized bed reactor with gaseous H₂O in a manner sufficient for said H₂O to adsorb to the surface of said titania particles to produce H₂O adsorbed titania particles; and
contacting said H₂O adsorbed titania particles with a gaseous Si containing reactant under conditions sufficient for said gaseous Si containing reactant to react with substantially all of said adsorbed H₂O to produce a compact coating of silica on the surface of said titania particles.

11. The process according to claim 10, wherein said titania particles have a diameter ranging from about 0.001 to 100μ.

12. The process according to claim 10, wherein said Si containing reactant is selected from the group consisting of silicon halides and organosilicons.

13. The process according to claim 12, wherein said Si containing reactant is a silicon halide.

14. The process according to claim 13, wherein said silicon halide is SiCl₄.

15. The process according to claim 13, wherein said Si containing reactant is an organosilicon.

16. The process according to claim 15, wherein said organosilicon is TEOS.

17. The process according to claim 10, wherein said process further comprises pretreating said titania particles to increase the energy of adsorption of said adsorbed H₂O.

18. A dry process for coating a titania particle with a compact silica layer, said process comprising:
introducing titania particles ranging in size from about 0.001 to 100μ into a fluidized bed reactor to produce a fluidized bed of titania particles;
introducing gaseous H₂O into said fluidized bed reactor in a manner sufficient for said H₂O to adsorb to the surface of said titania particles; and
introducing a gaseous silicon halide into said fluidized bed reactor under conditions sufficient for said silicon halide to react with substantially all of said adsorbed H₂O on said titania particles to produce a compact coating of silica on the surface of said titania particles;
whereby titania particles coated with a compact layer of silica are produced.

19. The process according to claim 18, wherein said silicon halide is SiCl₄.

20. The process according to claim 18, wherein said process further comprises pretreating said titania particles to increase the energy of adsorption of said adsorbed H₂O.

21. Coated titania particles produced according to the process of claim 1.

22. Coated titania particles produced according to the process of claim 10.

23. Coated titania particles produced according to the process of claim 18.
